(19) United States
(12) Patent Application Publication
(10) Pub. No.: US 2018/0155589 A1
(43) Pub. Date: Jun. 7, 2018

(54) POLYESTER POLYOL, POLYOL PREPARATION FOR LAMINATING ADHESIVE AGENT, RESIN COMPOSITION, CURABLE RESIN COMPOSITION, ADHESIVE AGENT FOR LAMINATING USE, AND BACK SHEET FOR SOLAR CELL

(71) Applicant: DIC Corporation, Tokyo (JP)

(72) Inventors: Akio Umino, Ichihara-shi (JP); Seiichi Uno, Ichihara-shi (JP); Masami Hozumi, Tokyo (JP); Kouji Akita, Tokyo (JP); Tetsuya Toda, Tokyo (JP)

(21) Appl. No.: 15/872,164

(22) Filed: Jan. 16, 2018

Related U.S. Application Data
(62) Division of application No. 14/916,034, filed on Mar. 3, 2016.

(30) Foreign Application Priority Data
Sep. 6, 2013 (JP) 2013-185013

(51) Int. Cl. C09J 167/02; C08G 18/44; B32B 7/12; B32B 15/04; B32B 27/32; B32B 27/36; C09J 167/00; C09D 175/06; C08L 67/02; C08G 63/181; C08G 63/127; C08G 18/75; C08G 18/66; H01L 31/049; C08G 18/32; C08G 18/28; C08G 18/12; C08G 18/08; H01L 51/44

(52) U.S. Cl. CPC C09J 167/02; Y02E 10/50; B32B 7/12; B32B 15/04; B32B 27/32; B32B 27/36; C09J 167/00; C09D 175/06; C08L 67/02; C08G 63/181; C08G 63/127; C08G 18/758; C08G 18/6659; H01L 31/049; C08G 18/3228; C08G 18/285; C08G 18/12; C08G 18/0823; B32B 27/365; B32B 2457/00; C08L 2205/03; C09J 2203/322; H01L 51/448; C08G 18/44

(57) ABSTRACT

Provided are a polyester polyol which exhibits a high adhesion strength after being cured in a case of being used as a main agent for an adhesive for lamination, an excellent temporal stability in which the adhesion strength is not deteriorated in a heat and moisture resistance test, and an excellent appearance after being subjected to a lamination processing, a resin composition using the same, a two-part adhesive for lamination which contains the resin composition, and a back sheet for a solar cell. Specifically, as a main agent for the two-part adhesive for lamination, a polyester polyol which has a resin structure obtained by reacting a branched alkylene diol, a long-chain aliphatic dicarboxylic acid having 8 to 20 carbon atoms, and an aromatic tricarboxylic acid, and has a weight average molecular weight (Mw) of 10,000 to 100,000 and a molecular weight distribution (Mw/Mn) of 3.0 to 4.7 is used.

### TECHNICAL FIELD

The present invention relates to a back sheet for a solar cell having excellent substrate adhesion and UV resistance under hot and humid conditions, an adhesive for lamination that is useful as an adhesive for the back sheet, a curable resin composition that constitutes the adhesive, a polyester polyol, a polyol for laminating an adhesive, and a resin composition that constitute the main agent of the curable resin composition.

### BACKGROUND ART

In recent years, there has been an increasing concern for depletion of fossil fuels such as petroleum and coal, and it is regarded as an urgent task to develop a technology for securing alternative energies obtained from these fossil fuels. Among these alternative energies to the fossil fuels, solar power generation in which solar energy can be directly converted into electrical energy has been put into practical use as a new semi-permanent and pollution-free energy source, and the cost performance in actual use has been remarkably improved, making the expectations as a clean energy source very high.

Solar cells used in solar power generation constitute the heart of a solar power generation system capable of directly converting solar energy into electrical energy and a solar cell is composed of a semiconductor represented by silicon and has a structure in which solar cell elements are wired in series or in parallel and are formed into a unit by various kinds of packaging for protecting the elements. The unit incorporated in such a package is called a solar cell module and generally has a configuration in which a surface exposed to sunlight is covered with glass, gaps are filled with a filling material composed of a thermoplastic resin, and the back surface is protected by a sealing sheet. For the filling material composed of a thermoplastic resin, an ethylene-vinyl acetate copolymer resin is frequently used because of high transparency and excellent moisture resistance. On the other hand, the back surface protection sheet (back sheet) is required to have properties such as mechanical strength, weather resistance, heat resistance, heat and moisture resistance, and light resistance. Since such a solar cell module is typically used outdoors for a long period of time as long as about 30 years, an adhesive constituting the back sheet is required to have adhesion strength with a certain degree of reliability for a long period of time and specifically have high adhesion to various films having different properties, such as a polyester film and a polyvinyl fluoride film, and a high level of heat and moisture resistance sufficient to maintain adhesion for a long period of time in outdoor environments.

There is known a technique in which, as such an adhesive for a back sheet, by using for example, a high molecular weight polyester polyol, obtained by using an aromatic dibasic acid, a C9 or higher aliphatic carboxylic acid and a C5 or higher aliphatic alcohol as raw material monomers and a low molecular weight polyester polyurethane polyol together as a main agent, and using a polyisocyanate compound as a curing agent, the cohesion of the resin is increased due to the aromatic dibasic acid and infiltration of moisture is prevented by increasing a distance between ester bonds by using a long-chain aliphatic alcohol so as to improve heat and moisture resistance, and coatability and wettability are improved by using the low molecular weight urethane in combination (for example, refer to PTL 1).

However, since the polyester polyol obtained by using a C9 or higher aliphatic carboxylic acid as the raw material is used in the adhesive disclosed in PTL 1, the heat and moisture resistance is slightly improved, but is not sufficient. In addition, there arise problems that the coating film after being cured is weak in strength and smoothness in appearance of the film after being subjected to a lamination processing is deteriorated.

### CITATION LIST

### Patent Literature

[PTL 1] Japanese Patent No. 4416047

### SUMMARY OF INVENTION

### Technical Problem

Accordingly, the problem to be solved by the present invention is to provide a polyester polyol which exhibits high adhesion strength after being cured in a case of being used as a main agent for an adhesive for lamination, excellent temporal stability in which the adhesion strength is not deteriorated in a heat and moisture resistance test, and excellent appearance after being subjected to a lamination processing, a resin composition using the same, a two-part adhesive for lamination which contains the resin composition, and a back sheet for a solar cell.

### Solution to Problem

As a result of conducting intensive investigation to solve the above problems, the inventors have found that a polyester polyol having a resin structure obtained by reacting a branched alkylene diol, a long-chain aliphatic dicarboxylic acid having 8 to 20 carbon atoms and an aromatic tricarboxylic acid and having a predetermined weight average molecular weight range and a predetermined molecular weight distribution, exhibits an excellent moisture resistance and also provides, in a case of using the polyester polyol as a main agent of an adhesive for an external film of a back sheet for a solar cell, an improved adhesion strength after being cured, a small temporal change under hot and humid conditions, and furthermore, an excellent appearance of the sheet after being subjected to a lamination processing. Thus, the present invention has been completed.

That is, the present invention is to provide a polyester polyol which has a resin structure obtained by reacting a branched alkylene diol, a long-chain aliphatic dicarboxylic acid having 8 to 20 carbon atoms and an aromatic tricarboxylic acid, and has a weight average molecular weight (Mw) of 10,000 to 100,000, and a molecular weight distribution (Mw/Mn) of 3.0 to 4.7.

The present invention is to further provide a polyol for a two-part adhesive for lamination, which includes the polyester polyol.

The present invention is to still further provide a resin composition which includes the polyester polyol and a polyfunctional epoxy compound as essential components.

The present invention is to still further provide a curable resin composition which is obtained by mixing the polyester diol or the resin composition as a main agent and an aliphatic polyisocyanate as a curing agent.

The present invention is to still further provide a two-part adhesive for lamination, which is composed of the curable resin composition.

The present invention is to still further provide a back sheet for a solar cell, which is formed of at least one film selected from the group consisting of a polyester film, a fluorine-based resin film, a polyolefin film and a metal foil, and an adhesive layer composed of a two-part adhesive for lamination, which is for laminating these films.

### Advantageous Effects of Invention

According to the present invention, it is possible to provide a polyester polyol which exhibits, in a case of being used as a main agent for an adhesive for lamination, a high adhesion strength after being cured, an excellent temporal stability in which the adhesion strength is not deteriorated in a heat and moisture resistance test, and an excellent appearance after being subjected to a lamination processing, a resin composition using the polyester polyol, a two-part adhesive for lamination which contains the resin composition, and a back sheet for a solar cell.

### BRIEF DESCRIPTION OF DRAWINGS

FIG. 1 is a GPC chart of a polyester polyol (A2) obtained in Example 2.

FIG. 2 is an infrared absorption spectrum of the polyester polyol (A2) obtained in Example 2.

### DESCRIPTION OF EMBODIMENTS

A polyester polyol according to the present invention is useful as a polyol for a two-part adhesive for lamination, which is a main agent of an adhesive of a back sheet for a solar cell, and can be obtained by reacting a branched alkylene diol, a long-chain aliphatic dicarboxylic acid having 8 to 20 carbon atoms, and an aromatic tricarboxylic acid as essential raw material components.

Here, the polyester polyol obtained by using a branched alkylene diol as a raw material is remarkably improved in the hydrolysis resistance, and in a case of using the polyester polyol as an adhesive for lamination, an adhesive having a small difference between initial adhesion and adhesion after being subjected to a heat and humid resistance test and an excellent heat and moisture resistance can be provided. Specifically, the branched alkylene diol is an alkylene diol having a tertiary carbon atom or a quaternary carbon atom in the molecular structure thereof and examples thereof include 1,2,2-trimethyl-1,3-propanediol, 2,2-dimethyl-3-isopropyl-1,3-propanediol, 3-methyl-1,3-butanediol, 3-methyl-1,5-pentanediol, neopentyl glycol, 1,4-bis(hydroxymethyl)cyclohexane, and 2,2,4-trimethyl-1,3-pentanediol. Among these, from the viewpoint of excellent heat and moisture resistance, neopentyl glycol is particularly preferable.

In addition, since a long-chain aliphatic dicarboxylic acid having 8 to 20 carbon atoms is used, the viscosity of the polyester polyol obtained is decreased and adhesion to a substrate can be improved. Additionally, the viscosity of the polyester polyol is decreased and in a case of using the polyester polyol as an adhesive for lamination, the appearance of the obtained sheet after being subjected to a lamination processing is improved.

Examples of the long-chain aliphatic dicarboxylic acid having 8 to 20 carbon atoms include suberic acid, azelaic acid, sebacic acid, undecanedioic acid, dodecanedioic acid, tridecanedioic acid, tetradecanedioic acid, pentadecanedioic acid, hexadecanedioic acid, heptadecanedioic acid, octadecanedioic acid, nonadecanedioic acid, and icosanedioic acid.

Among these, from the viewpoint of obtaining a remarkable effect of improving the adhesion to a substrate, aliphatic polybasic acids having 8 to 13 carbon atoms such as suberic acid, azelaic acid, sebacic acid, undecanedioic acid, dodecanedioic acid, tridecanedioic acid, 1,2,5-hexanetricarboxylic acid and 1,2,4-cyclohexanetricarboxylic acid are particularly preferable.

Next, since an aromatic tricarboxylic acid is used, the heat resistance of a cured product becomes satisfactory and the molecular weight distribution of the polyester polyol obtained becomes broad. Thus, adhesion to a substrate is improved and in a case of using the polyester polyol as an adhesive for lamination, the heat and moisture resistance becomes satisfactory. Specific examples of the aromatic tricarboxylic acid include aromatic tribasic acids such as trimellitic acid, trimellitic anhydride, 1,2,5-benzenetricarboxylic acid, 2,5,7-naphthalenetricarboxylic acid and pyromellitic anhydride, and anhydrides thereof.

The polyester polyol of the present invention is obtained by reacting the above-described, branched alkylene diol, long-chain aliphatic dicarboxylic acid having 8 to 20 carbon atoms, and aromatic tricarboxylic acid as essential raw material components. However, for the purpose of improving flexibility and wettability as an adhesive, within a range without impairing the effects of the present invention, in addition to the respective raw material components, linear alkanediols such as ethylene glycol, 1,3-propylene glycol, 1,4-butanediol, 1,6-hexanediol, 1,8-nonanediol, and diethylene glycol may be further used or a branched alkane structure containing trifunctional alcohol such as trimethylol propan may be used. In a case of using a branched alkane structure containing trifunctional alcohol, from the viewpoint of not causing an excessive viscosity increase and obtaining an appropriate branched structure, the mass ratio between the branched alkylene diol and the branched alkane structure containing trifunctional alcohol [branched alkane diol/branched alkane structure containing trifunctional alcohol] is preferably from 90/10 to 99/1.

Further, in the present invention, as a carboxylic acid component, for the purpose of adjusting the molecular weight and the viscosity of a new polyester polyol to be finally obtained, monocarboxylic acids such as methanoic acid, ethanoic acid, propionic acid, butanoic acid, pentanoic acid, hexanoic acid, heptanoic acid, octanoic acid, nonanoic acid, decanoic acid, dodecanoic acid, tetradecanoic acid, hexadecanoic acid, heptadecanoic acid, octadecanoic acid, and benzoic acid may be used in combination with the above-described long-chain aliphatic dicarboxylic acid having 8 to 20 carbon atoms.

As a method of preparing the polyester polyol of the present invention using the above-described respective components, for example, a method of reacting a branched alkylene diol, a long-chain aliphatic dicarboxylic acid having 8 to 20 carbon atoms, and an aromatic tricarboxylic acid, as essential raw material components, under the presence of an esterification catalyst in a temperature range of 150° C. to 270° C. and the like may be used. Examples of the esterification catalyst used herein include an organotin compound, an inorganotin compound, an organotitanium compound, and an organozinc compound.

The polyester polyol thus obtained has a weight average molecular weight (Mw) of 10,000 to 100,000 and a molecular weight distribution (Mw/Mn) of 3.0 to 4.7. In a case in which the weight average molecular weight (Mw) is less than 10,000, the initial adhesion strength tends to decrease, and the viscosity is low, thereby forming a resin composition on which uniform coating is hardly achieved. In a case in which the weight average molecular weight (Mw) is more than 100,000, the viscosity of a resin composition is increased and thus it is required that the resin composition be diluted with a large amount of a solvent at the time of coating. In addition, since the thickness of an adhesive layer is decreased, the initial adhesion strength tends to decrease and a high temperature and a long period of time are required in a step of drying the solvent, thereby causing an adverse effect on production costs and the environment.

Moreover, in a case in which the molecular weight distribution (Mw/Mn) of the polyester polyol is less than 3, adhesion to a substrate is decreased in a case of using the polyester polyol as a two-part adhesive for lamination, so that adhesion strength after being cured and heat and moisture resistance are deteriorated. On the other hand, in a case in which the molecular weight distribution (Mw/Mn) is more than 4.7, in a case of using the polyester polyol as a two-part adhesive for lamination, adhesion strength after being cured tends to be decreased. From the viewpoint of the adhesion strength to a substrate, the molecular weight distribution (Mw/Mn) of the polyester polyol is more particularly preferably from 3.0 to 4.5.

In addition, in the present invention, the weight average molecular weight (Mw) and the number average molecular weight (Mn) of the polyester polyol are values measured by gel permeation chromatography (GPC) under the following conditions.

Measurement apparatus: HLC-8220 GPC (manufactured by Tosoh Corporation)

Columns: TSK-GUARDCOLUMN Super HZ-L (manufactured by Tosoh Corporation) and TSK-GEL Super HZM-M×4 (manufactured by Tosoh Corporation)

Detector: differential refractive index (RI) detector

Data processing: Multistation GPC-8020 model II (manufactured by Tosoh Corporation)

Measurement conditions: Column temperature 40° C.
Solvent tetrahydrofuran
Flow rate 0.35 ml/min

Standard: monodisperse polystyrene

Sample: microfiltered resin solution in tetrahydrofuran with solid content of 0.2% by mass (100 μl)

The polyester polyol preferably has a hydroxyl value of from 5 to 30 mgKOH/g and more preferably from 7 to 15 mgKOH/g from the viewpoint that the resin composition has high adhesion to a substrate under hot and humid conditions.

The aforementioned polyester polyol of the present invention is useful as a polyol as a main agent of a two-part adhesive for lamination and can be used together with a curing agent. However, in the present invention, a resin composition that contains the polyester polyol (hereinafter, referred to as “polyester polyol (A)”) and a polyfunctional epoxy compound (B) is preferably used as a main agent of a two-part adhesive for lamination. That is, in a case in which the polyfunctional epoxy compound (B) is used together with the polyester polyol (A), a carboxy group produced by hydrolysis of the polyester polyol (A) when an adhesive layer absorbs moisture is captured by an epoxy group in the polyfunctional epoxy compound (B), whereby the heat and moisture resistance of the adhesive layer can be further improved. The polyfunctional epoxy compound (B) is preferably an epoxy resin containing a hydroxyl group having a number average molecular weight (Mn) of 300 to 5,000. That is, in a case in which the number average molecular weight (Mn) is 300 or more, in addition to heat and moisture resistance, adhesion strength to a substrate becomes more satisfactory and in a case in which the number average molecular weight (Mn) is 5,000 or less, compatibility with the polyester polyol (A) is satisfactory. From the viewpoint of achieving an excellent balance therebetween, among these ranges, the number average molecular weight (Mn) is preferably from 400 to 2,000.

Since a resin composition having further excellent curability can be obtained, the polyfunctional epoxy compound (B) preferably has a hydroxyl value of 30 to 160 mgKOH/g and more preferably has a hydroxyl value of 50 to 150 mgKOH/g.

Examples of the polyfunctional epoxy compound (B) include bisphenol epoxy resins such as bisphenol A epoxy resin and bisphenol F epoxy resin; biphenyl epoxy resins such as biphenyl epoxy resin and tetramethylbiphenyl epoxy resin; and dicyclopentadiene-phenol addition reaction epoxy resins. These may be used alone or in a combination of two or more. Among these, bisphenol epoxy resins are preferably used from the viewpoint of obtaining a resin composition having high adhesion to a substrate under hot and humid conditions and high initial adhesion strength.

Further, by using a hydroxyl group-containing aliphatic polycarbonate (C) together with the polyester polyol (A) and the polyfunctional epoxy compound (B) in the resin composition, the crosslinking density of a cured product can be remarkably improved and adhesion to a substrate can be further increased.

The hydroxyl group-containing aliphatic polycarbonate (C) used herein preferably has a number average molecular weight (Mn) of 500 to 3,000 from the viewpoint that the hydroxyl group concentration is increased to an appropriate degree and the crosslinking density at the time of curing is remarkably improved and more particularly preferably has a number average molecular weight (Mn) of 800 to 2,000. Herein, the number average molecular weight (Mn) is measured under the same conditions as the conditions for GPC measurement of the above-described polyester polyol.

The hydroxyl group-containing aliphatic polycarbonate (C) preferably has a hydroxyl value of 20 to 300 mgKOH/g and more particularly preferably has a hydroxyl value of 40 to 250 mgKOH/g from the viewpoint of obtaining a resin composition having further excellent curability. In addition, the polycarbonate is preferably a polycarbonate diol from the viewpoint of providing an excellent adhesion to a substrate under hot and humid conditions.

The hydroxyl group-containing aliphatic polycarbonate (C) can be produced, for example, by a polycondensation reaction of a polyalcohol with a carbonylation agent.

As a polyalcohol used for the production of the hydroxyl group-containing aliphatic polycarbonate (C), for example, either of a branched alkane polyol, which is the raw material of the polyester diol, and a non-branched alkane diol can be used.

In addition, examples of a carbonylation agent used for the production of the hydroxyl group-containing aliphatic polycarbonate (C) include ethylene carbonate, propylene carbonate, dimethyl carbonate, diethyl carbonate, dibutyl carbonate, and diphenyl carbonate. These may be used alone or in a combination of two or more.

When the resin composition of the present invention contains the polyester polyol (A), the polyfunctional epoxy compound (B) and the hydroxyl group-containing aliphatic polycarbonate resin (C) in such a range that the amount of the polyfunctional epoxy compound (B) is 5 to 20 parts by mass and the amount of the polycarbonate resin (C) is 5 to 20 parts by mass with respect to 100 parts by mass of the polyester polyol (A), the resin composition has an excellent adhesion to various substrates and can maintain a high adhesion to substrates under hot and humid conditions. Thus, this case is preferable.

The resin composition of the present invention may contain a hydroxyl group-containing compound other than the polyester polyol (A), the polyfunctional epoxy compound (B) and the hydroxyl group-containing aliphatic polycarbonate resin (C). Examples of such a hydroxyl group-containing compound include polyester polyols obtained by reacting a polybasic acid and a polyalcohol, polyester polyurethane polyols having a number average molecular weight (Mn) of less than 25,000 which is obtained by reacting a polybasic acid, a polyalcohol and a polyisocyanate, linear polyester polyurethane polyols obtained by reacting a dibasic acid, a diol and a diisocyanate, ether glycols such as polyoxyethylene glycol and polyoxypropylene glycol, bisphenols such as bisphenol A and bisphenol F, and alkylene oxide adducts of bisphenols obtained by adding ethylene oxide, propylene oxide, and the like to the bisphenols. These may be used alone or in a combination of two or more.

In a case in which the resin composition of the present invention contains a hydroxyl group-containing compound other than the polyester polyol (A), the polyfunctional epoxy compound (B) and the hydroxyl group-containing aliphatic polycarbonate (C), the content thereof is preferably from 5 to 20 parts by mass with respect to 100 parts by mass of the polyester polyol (A) since resin composition exhibits an excellent adhesion to various substrates and can maintain a high adhesion to substrates under hot and humid conditions.

With respect to the curable resin composition of the present invention, the polyol for an adhesive for lamination including the polyester polyol (A) or the resin composition including the respective components of (A) to (C) is used as the main agent and an aliphatic polyisocyanate (D) is used as the curing agent.

Examples of the aliphatic polyisocyanate (D) include the various polyisocyanates. These aliphatic polyisocyanates (D) may be used alone or in a combination of two or more.

Among these aliphatic polyisocyanates (D), nurate type polyisocyanate compounds are preferably used from the viewpoint of an excellent adhesion to a substrate under hot and humid conditions.

In the present invention, regarding the mixing ratio of the aliphatic polyisocyanate (D), from the viewpoint of obtaining a curable resin composition having a further excellent curability, a ratio [OH]/[NCO] between the total number of moles [OH] of hydroxyl groups contained in the polyester polyol (A), the epoxy compound (B) and the hydroxyl group-containing polycarbonate resin (C) and the number of moles [NCO] of isocyanate groups contained in the aliphatic polyisocyanate (D) is preferably from 1/1 to 1/2 and more preferably from 1/1.05 to 1/1.5.

In addition, in a case in which the resin composition used as the main agent contains a hydroxyl group-containing compound other than the polyester polyol (A), the polyfunctional epoxy compound (B) and the hydroxyl group-containing polycarbonate (C), regarding the mixing ratio of the aliphatic polyisocyanate (D), the ratio [OH]/[NCO] between the total number of moles [OH] of hydroxyl groups contained in the curable resin composition and the number of moles [NCO] of isocyanate groups contained in the polyisocyanate compound (D) is preferably from 1/1 to 1/2 and more preferably from 1/1.05 to 1/1.5.

The curable resin composition of the present invention may contain various solvents. Examples of the solvent include ketone compounds such as acetone, methyl ethyl ketone (MEK), and methyl isobutyl ketone, cyclic ether compounds such as tetrahydrofuran (THF) and dioxolane, ester compounds such as methyl acetate, ethyl acetate, and butyl acetate, aromatic compounds such as toluene and xylene, and alcohol compounds such as carbitol, cellosolve, methanol, isopropanol, butanol, and propylene glycol monomethyl ether. These may be used alone or in a combination of two or more.

The curable resin composition of the present invention may further contain various additives such as a ultraviolet absorbers, antioxidants, silicon-based additives, fluorine-based additives, rheology control agents, defoaming agents, antistatic agents, and antifogging agents.

The curable resin composition of the present invention is useful as a two-part adhesive for lamination for bonding various plastic films.

Examples of the plastic film to be used for lamination herein include films of polycarbonate, polyethylene terephthalate, polymethyl methacrylate, polystyrene, polyester, polyolefin, epoxy resin, melamine resin, triacetylcellulose resin, polyvinyl alcohol, ABS resin, norbornene resin, cyclic olefin resin, polyimide resin, polyvinyl fluoride resin, and polyvinylidene fluoride resin. The two-part adhesive for lamination of the present invention exhibits a high adhesion to films of polyvinyl fluoride resin and polyvinylidene fluoride resin, which particularly exhibits a poor adhesion among these various films.

When the various films are bonded together, the two-part adhesive for lamination of the present invention is preferably used in an amount of 2 to 50 g/m².

A laminated film obtained by bonding plural films using the two-part adhesive for lamination of the present invention is characterized in that the laminated film exhibits a high adhesion under hot and humid conditions and the films do not peel off easily. Therefore, the two-part adhesive for lamination of the present invention can be suitable for laminated films used in harsh environments such as outdoors and as described above, can be thus preferably used as an adhesive at the time of production of a back sheet for a solar cell.

As a method of producing a back sheet for a solar cell using the two-part adhesive for lamination of the present invention, for example, a method including applying the two-part adhesive for lamination of the present invention to a plastic film, laminating another plastic substrate on the curable resin composition layer, and then curing the laminate under a temperature condition of 25° C. to 80° C. to obtain a sheet molded body may be used.

Examples of a coater usable for applying the two-part adhesive for lamination of the present invention to the plastic film include a comma coater, a roll knife coater, a die coater, a roll coater, a bar coater, a gravure roll coater, a reverse roll coater, a blade coater, a gravure coater, and a micro gravure coater. In addition, the amount of the two-part adhesive for lamination applied to the plastic substrate is preferably approximately from 1 to 50 μm in terms of a dried film thickness.

Plural plastic films and adhesive layers may be present. In addition, a structure in which a gas barrier layer such as a metal deposition film or the like is provided on the surface of the plastic film, the two-part adhesive for lamination is applied to the gas barrier layer, and another plastic film is laminated thereon may be adopted. Further, in order to improve adhesion with a sealing material for sealing a solar cell element, an easily adhering layer may be provided on the sealing material side surface of the back sheet for a solar cell. The easily adhering layer can have unevenness on the surface of the easily adhering layer and is preferably composed of metal fine particles of TiO₂, SiO₂, CaCO₃, SnO₂, ZrO₂, MgCO₃, and the like and a binder in order to improve the adhesion.

In addition, the thickness of the adhesive layer in the back sheet for a solar cell of the present invention is from 1 to 50 μm and particularly preferably from 5 to 15 μm.

Further, a solar cell module formed by using the back sheet for a solar cell can be produced by arranging an ethylene-vinyl acetate resin (EVA) sheet, plural solar cells, an ethylene-vinyl acetate resin (EVA) sheet, and the back sheet of the present invention on a cover glass plate, and heating under evacuation to dissolve the EVA sheet, thereby sealing the solar cell elements. At this time, the plural solar cell elements are joined in series by an interconnector. Here, examples of the solar cell elements include single crystal silicon-based solar cell elements, polycrystalline silicon-based solar cell elements, single-junction or tandem-structure amorphous silicon-based solar cell elements, semiconductor-based solar cell elements with III-V Group compounds such as gallium-arsenic (GaAs), indium-phosphorus (InP) and the like, semiconductor-based solar cell elements with II-VI Group compounds such as cadmium-tellurium (CdTe) and the like, semiconductor-based solar cell elements with I-III-VI Group compounds such as copper/indium/selenium (CIS-based), copper/indium/gallium/selenium (CIGS-based), copper/indium/gallium/selenium/sulfur (CIGSS-based) and the like, dye-sensitized solar cell elements, and organic solar cell elements.

### EXAMPLE

The present invention is further illustrated by the following specific examples of synthesis and implementation, although the present invention is not limited thereto. Incidentally, “part(s)” is on a mass basis unless otherwise specified.

In addition, in the examples herein, the number average molecular weight (Mn) and the weight average molecular weight (Mw) were measured by gel permeation chromatography (GPC) under the following conditions.

Measurement apparatus: HLC-8220 GPC (manufactured by Tosoh Corporation)

Columns: TSK-GUARDCOLUMN Super HZ-L (manufactured by Tosoh Corporation) and TSK-GEL Super HZM-M×4 (manufactured by Tosoh Corporation)

Detector: differential refractive index (RI) detector

Data processing: Multistation GPC-8020 model II (manufactured by Tosoh Corporation)

Measurement conditions:
Column temperature: 40° C.
Solvent: tetrahydrofuran
Flow rate: 0.35 ml/min

Standard: monodisperse polystyrene

Sample: microfiltered resin solution in tetrahydrofuran with solid content of 0.2% by mass (100 μl)

In addition, the infrared absorption spectrum was obtained by applying the solution of the polyester polyol (A) to a KBr plate, causing the solvent to volatilize, and preparing a sample for measurement.

### Example 1 [Synthesis of Polyester Polyol (A1)]

A flask equipped with a stirrer, a temperature sensor, and a rectifying column was charged with 788 parts of neopentyl glycol, 21 parts of trimethylolpropane, 578 parts of isophthalic acid, 272 parts of phthalic anhydride, 419 parts of sebacic acid, 17 parts of trimellitic anhydride, and 0.2 parts of an organotitanium compound. The mixture was heated to 230° C. to 250° C. with stirring while allowing dry nitrogen to flow through the flask to conduct an esterification reaction. The reaction was terminated when the acid value was 1.0 mgKOH/g or less. The reaction product was cooled to 100° C. and then was diluted with ethyl acetate to a solid content of 62%. Thus, a polyester polyol (A1) having a weight average molecular weight (Mw) of 48,000, a molecular weight distribution (Mw/Mn) of 4.5, a hydroxyl value of 19, and a glass transition temperature (Tg) of 10° C. was obtained.

### Example 2 [Synthesis of Polyester Polyol (A2)]

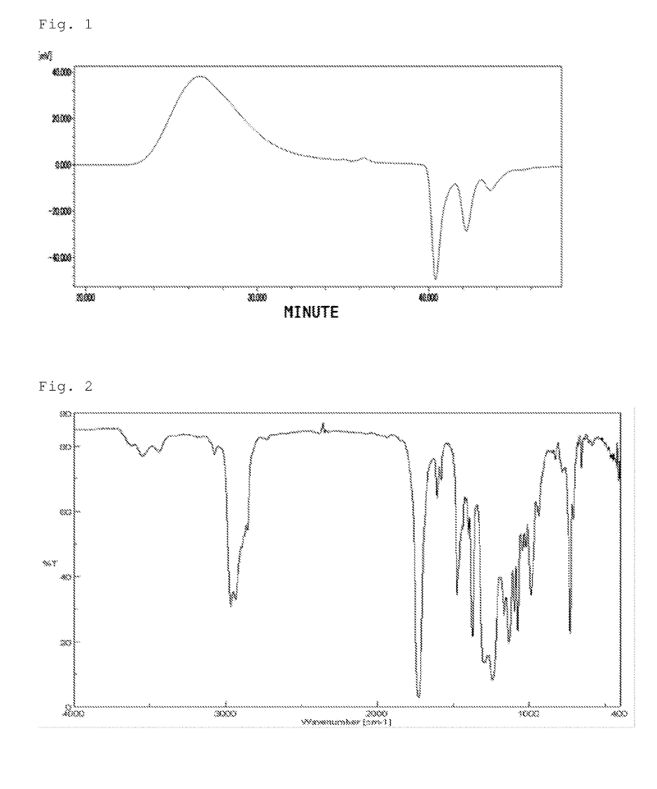

A flask equipped with a stirrer, a temperature sensor, and a rectifying column was charged with 836 parts of neopentyl glycol, 588 parts of isophthalic acid, 274 parts of phthalic anhydride, 406 parts of sebacic acid, 15.2 parts of trimellitic anhydride, and 0.2 parts of an organotitanium compound. The mixture was heated to 230° C. to 250° C. with stirring while allowing dry nitrogen to flow through the flask to conduct an esterification reaction. The reaction was terminated when the acid value was 1.0 mgKOH/g or less. The reaction product was cooled to 100° C. and then was diluted with ethyl acetate to a solid content of 62%. Thus, a polyester polyol (A2) having a weight average molecular weight (Mw) of 25,000, a molecular weight distribution (Mw/Mn) of 3.2, a hydroxyl value of 10, and a glass transition temperature (Tg) of 6° C. was obtained. The GPC chart of the obtained polyester polyol (A2) is shown in FIG. 1 and the infrared absorption spectrum is shown in FIG. 2.

### Example 3 [Synthesis of Polyester Polyol (A3)]

A flask equipped with a stirrer, a temperature sensor, and a rectifying column was charged with 794 parts of neopentyl glycol, 511 parts of isophthalic acid, 272 parts of phthalic anhydride, 230 parts of sebacic acid, 261 parts of dodecanedioic acid, 21 parts of trimellitic anhydride, and 0.2 parts of an organotitanium compound. The mixture was heated to 230° C. to 250° C. with stirring while allowing dry nitrogen to flow through the flask to conduct an esterification reaction. The reaction was terminated when the acid value was 1.0 mgKOH/g or less. The reaction product was cooled to 100° C. and then was diluted with ethyl acetate to a solid content of 62%. Thus, a polyester polyol (A3) having a weight average molecular weight (Mw) of 24,000, a molecular weight distribution (Mw/Mn) of 3.5, a hydroxyl value of 18, and a glass transition temperature (Tg) of −5° C. was obtained.

### Comparative Example 1 [Synthesis of Polyester Polyol (a1)]

A flask equipped with a stirrer, a temperature sensor, and a rectifying column was charged with 1,088 parts of neopentyl glycol, 727 parts of isophthalic acid, 353 parts of phthalic anhydride, 524 parts of sebacic acid, and 0.2 parts of an organotitanium compound. The mixture was heated to 240° C. to 260° C. with stirring while allowing dry nitrogen to flow through the flask to conduct an esterification reaction. The reaction was terminated when the acid value was 0.5 mgKOH/g or less. The reaction product was cooled to 100° C. and then was diluted with ethyl acetate to a solid content of 62%. Thus, a polyester polyol (a1) having a weight average molecular weight (Mw) of 78,000, a molecular weight distribution (Mw/Mn) of 2.5, a hydroxyl value of 5, and a glass transition temperature (Tg) of −10° C. was obtained.

### Comparative Example 2 [Synthesis of Polyester Polyol (a2)]

A flask equipped with a stirrer, a temperature sensor, and a rectifying column was charged with 843 parts of neopentyl glycol, 519 parts of isophthalic acid, 694 parts of phthalic anhydride, and 0.02 parts of an organotitanium compound. The mixture was heated to 230° C. to 250° C. with stirring while allowing dry nitrogen to flow through the flask to conduct an esterification reaction. The reaction was terminated when the acid value was 1.0 mgKOH/g or less. The reaction product was cooled to 100° C. and then was diluted with ethyl acetate to a solid content of 62%. Thus, a polyester polyol (a2) having a weight average molecular weight (Mw) of 13,000, a molecular weight distribution (Mw/Mn) of 2.2, a hydroxyl value of 20, and a glass transition temperature (Tg) of 35° C. was obtained.

### Comparative Example 3 [Synthesis of Polyester Polyol (a3)]

A flask equipped with a stirrer, a temperature sensor, and a rectifying column was charged with 862 parts of neopentyl glycol, 389 parts of isophthalic acid, 520 parts of phthalic anhydride, 313 parts of adipic acid, and 0.02 parts of an organotitanium compound. The mixture was heated to 230° C. to 250° C. with stirring while allowing dry nitrogen to flow through the flask to conduct an esterification reaction. The reaction was terminated when the acid value was 1.0 mgKOH/g or less. The reaction product was cooled to 100° C. and then was diluted with ethyl acetate to a solid content of 62%. Thus, a polyester polyol (a3) having a weight average molecular weight (Mw) of 15,000, a molecular weight distribution (Mw/Mn) of 2.1, a hydroxyl value of 18, and a glass transition temperature (Tg) of 20° C. was obtained.

### Comparative Example 4 [Synthesis of Polyester Polyol (a4)]

A flask equipped with a stirrer, a temperature sensor, and a rectifying column was charged with 1,130 parts of neopentyl glycol, 759 parts of isophthalic acid, 342 parts of phthalic anhydride, 534 parts of sebacic acid, and 1.2 parts of an organotitanium compound. The mixture was heated to 230° C. to 250° C. with stirring while allowing dry nitrogen to flow through the flask to conduct an esterification reaction. The reaction was terminated when the acid value was 1.0 mgKOH/g or less. The reaction product was cooled to 100° C. and then was diluted with ethyl acetate to a solid content of 80%. Next, 108 parts of hexamethylene diisocyanate was added thereto and heated to 70° C. to 80° C. with stirring while allowing dry nitrogen to flow through the flask to conduct a urethanation reaction. The reaction was terminated when the content of isocyanate reached 0.3% or less. Thus, a polyester polyol having a number average molecular weight of 10,000, a weight average molecular weight of 22,000, and a hydroxyl value of 9 was obtained. A resin solution having a solid content of 62% obtained by diluting the obtained polyester polyol with ethyl acetate was adopted as a polyester polyol (a4).

### Examples 4 to 12 and Comparative Examples 5 to 8

Using an epoxy resin of a bisphenol A epoxy resin (“EPICLON 860” manufactured by DIC Corporation) having a number average molecular weight (Mn) of 470 and an epoxy equivalent of 245 g/eq as a polyfunctional epoxy compound (B1), an epoxy resin of a bisphenol A epoxy resin (“JER 1001” manufactured by Mitsubishi Chemical Corporation) having a number average molecular weight (Mn) of 900 and an epoxy equivalent of 475 g/eq as a polyfunctional epoxy compound (B2), and PRACCEL CD210 (manufactured by Daicel Corporation) having a number average molecular weight of about 1,000 and hydroxyl value of about 110 as a polycarbonate (C), main agents for adhesives were prepared according to Tables 1 and 2.

As a polyisocyanate of a curing agent of an adhesive, a nurate type hexamethylene diisocyanate (D), Sumidur N3300 (manufactured by Sumitomo Bayer Urethane Co., Ltd.) was used.

With the composition shown in Tables 1 and 2, a main agent containing a polyester polyol, an epoxy compound and a polycarbonate, and a curing agent were collectively mixed to prepare each adhesive. In addition, mixing amounts shown in Tables are solid contents (parts by mass), and the amount of the curing agent mixed is an amount to be mixed with respect to 100 parts by mass of the main agent.

(Preparation of Evaluation Sample)

Each adhesive composition prepared above was applied to a PET film having a thickness of 125 μm (“X10S” from Toray Industries, Inc.), used as a substrate, such that the mass of the solid left after drying the solvent was 5 to 6 g/m². As a film for lamination, a fluorine film having a thickness of 25 μm (AFLEX 25PW, manufactured by Asahi Glass Co., Ltd.) was used and thus an evaluation sample was obtained. The evaluation sample was aged at 50° C. for 72 hours and then used for evaluation.

(Evaluation Method)

Evaluation 1: Appearance

The appearance of lamination of the evaluation samples prepared in the above manner was visually evaluated from the fluorine film side.

A: The film surface is smooth.

B: There are some craters on the film surface.

C: There are a large number of craters (recesses) on the film surface.

Evaluation 2: Measurement of Adhesion under Hot and Humid Conditions

The strength of the evaluation sample prepared in the above manner was measured by a T-peel test using a tensile testing machine (“AGS 500NG” manufactured by Shimadzu Corporation) in N/15 mm at a peel speed of 300 mm/min, and the obtained strength was evaluated as adhesion.

The initial adhesion of the evaluation sample and the adhesion of the sample after exposure to an environment at 121° C. and a humidity of 100% for 25 hours, 50 hours, and 75 hours were measured.

Evaluation 3: Evaluation of Heat and Moisture Resistance

The initial adhesion of the evaluation sample measured in Evaluation 2 was compared with the adhesion of the sample after exposure to an environment at 121° C. and a humidity of 100% for 75 hours. A sample whose adhesion after exposure was 80% or more of the initial adhesion was evaluated as A. A sample whose adhesion after exposure was 65% or more and less than 80% of the initial adhesion was evaluated as B. A sample whose adhesion after exposure was 40% or more and less than 65% of the initial adhesion was evaluated as C. A sample whose adhesion after exposure was less than 40% of the initial adhesion was evaluated as D.

TABLE 1

| | | Exam- | Exam- | Exam- | Exam- | Exam- | Exam- | Exam | Exam- | Exam- |
|---|---|---|---|---|---|---|---|---|---|---|
| | | ple 4 | ple 5 | ple 6 | ple 7 | ple 8 | ple 9 | ple 10 | ple 11 | ple 12 |
| Mixing | Polyester polyol (A1) | 100 | | | 100 | 100 | 100 | 100 | 100 | 100 |
| composition | Polyester polyol (A2) | | 100 | | | | | | | |
| | Polyester polyol (A3) | | | 100 | | | | | | |
| | Polyester polyol (a1) | | | | | | | | | |
| | Polyester polyol (a2) | | | | | | | | | |
| | Polyester polyol (a3) | | | | | | | | | |
| | Polyester polyol (a4) | | | | | | | | | |
| | Epoxy compound (B1) | 10 | 10 | 10 | 5 | 20 | 10 | 10 | | 10 |
| | Epoxy compound (B2) | | | | | | | 10 | | |
| | Polycarbonate (C) | 10 | 10 | 10 | 10 | 10 | 5 | 20 | 10 | 10 |
| | Curing agent (D) | 10 | 10 | 10 | 10 | 10 | 10 | 10 | 10 | 20 |
| Evaluation | Appearance | A | A | A | A | A | A | A | A | A |
| | Adhesion after aging | 7 | 7.1 | 7 | 7.4 | 6.4 | 7.5 | 6.5 | 6.9 | 6.6 |
| | (N/15 mm) | | | | | | | | | |
| | Adhesion after 121° C. | 6.3 | 6.4 | 6.4 | 6.7 | 6.1 | 6.8 | 6.2 | 6.3 | 6.2 |
| | and 100% for 25 hours | | | | | | | | | |
| | (N/15 mm) | | | | | | | | | |
| | Adhesion after 121° C. | 5.7 | 5.6 | 5.7 | 6.2 | 5.9 | 6.1 | 5.8 | 6 | 5.8 |
| | and 100% for 50 hours | | | | | | | | | |
| | (N/15 mm) | | | | | | | | | |
| | Adhesion after 121° C. | 5 | 5 | 5.1 | 5.1 | 5.5 | 5 | 5.4 | 5.1 | 5.4 |
| | and 100% for 75 hours | | | | | | | | | |
| | (N/15 mm) | | | | | | | | | |
| | Heat and Moisture | B | B | B | B | A | B | A | B | A |
| | Resistance | | | | | | | | | |

TABLE 2

| | | Comparative | Comparative | Comparative | Comparative |
|---|---|---|---|---|---|
| | | Example 5 | Example 6 | Example 7 | Example 8 |
| Mixing | Polyester polyol (A1) | | | | |
| composition | Polyester polyol (A2) | | | | |
| | Polyester polyol (A3) | | | | |
| | Polyester polyol (a1) | 100 | | | |
| | Polyester polyol (a2) | | 100 | | |
| | Polyester polyol (a3) | | | 100 | |
| | Polyester polyol (a4) | 40 | | | 100 |
| | Epoxy compound (B1) | 30 | 10 | 10 | 10 |
| | Epoxy compound (B2) | | | | |
| | Polycarbonate (C) | 24 | 10 | 10 | 10 |
| | Curing agent (D) | 10 | 10 | 10 | 10 |
| Evaluation | Appearance | A | A | A | C |
| | Adhesion after aging | 6.5 | 5 | 5.5 | 5 |
| | (N/15 mm) | | | | |
| | Adhesion after 121° C. | 5.5 | 3.7 | 3.9 | 4.1 |
| | and 100% for 25 hours | | | | |
| | (N/15 mm) | | | | |
| | Adhesion after 121° C. | 4.9 | 3 | 3 | 3.3 |
| | and 100% for 50 hours | | | | |
| | (N/15 mm) | | | | |
| | Adhesion after 121° C. | 4.0 | 2.5 | 2.2 | 2.1 |
| | and 100% for 75 hours | | | | |
| | (N/15 mm) | | | | |
| | Heat and Moisture | C | C | D | D |
| | Resistance | | | | |

1-5. (canceled)

6. The resin composition comprising, as essential components:
the polyester polyol (A);
the polyfunctional epoxy compound (B); and
a hydroxyl group-containing aliphatic polycarbonate (C),
wherein the polyester polyol (A) has a resin structure obtained by reacting a branched alkylene diol, a long-chain aliphatic dicarboxylic acid having 8 to 20 carbon atoms and an aromatic tricarboxylic acid, and which has a weight average molecular weight (Mw) of 10,000 to 100,000 and a molecular weight distribution (Mw/Mn) of 3.0 to 4.7.

7-9. (canceled)

10. The resin composition according to claim 6,
wherein the polyester polyol (A) is obtained by further using an aromatic dicarboxylic acid as a raw material component, in addition to the branched alkylene diol, the long-chain aliphatic dicarboxylic acid having 8 to 20 carbon atoms and the aromatic tricarboxylic acid, to perform the reaction.

11. The resin composition according to claim 6,
wherein the polyester polyol (A) has a hydroxyl value of 2 to 30 mgKOH/g.
